(19) United States
(12) Patent Application Publication
(10) Pub. No.: US 2023/0324803 A1
(43) Pub. Date: Oct. 12, 2023

(54) GAS-PHASE METHOD OF FORMING RADIATION-SENSITIVE PATTERNABLE MATERIAL

(71) Applicant: ASM IP Holding, B.V., Almere (NL)

(72) Inventors: Jan Deckers, Kessel-Lo (Leuven) (BE); Timothee Blanquart, Oud-Heverlee (BE); René Henricus Jozef Vervuurt, Leuven (BE); David Kurt de Roest, Leuven (BE); Kishan Ashokbhai Patel, Leuven (BE); Yoann Tomczak, Leuven (BE)

(21) Appl. No.: 18/131,279

(22) Filed: Apr. 5, 2023

Related U.S. Application Data
(60) Provisional application No. 63/327,977, filed on Apr. 6, 2022.

(51) Int. Cl. G03F 7/16; G03F 7/075; G03F 7/40; G03F 7/004

(52) U.S. Cl. CPC G03F 7/167; G03F 7/0757; G03F 7/40; G03F 7/0042

(57) ABSTRACT

Gas-phase methods of forming radiation-sensitive, patternable material and systems for forming the material. Exemplary methods include gas-phase formation of a layer comprising a polymeric material that forms the radiation-sensitive, patternable material on a surface of the substrate. Portions of the layer comprising the polymeric material can be exposed to radiation or active species to form exposed and unexposed regions. Material can be selectively deposed onto the exposed or unexposed portions and/or one of the exposed and unexposed regions can be selectively removed. One or more method steps can be performed within a reaction chamber and/or a reactor system.

### FIELD OF INVENTION

The present disclosure generally relates to methods of forming structures suitable for use in the manufacture of electronic devices. More particularly, the disclosure relates to methods of forming radiation-sensitive, patternable material on a surface of a substrate and to reactor systems for performing the methods.

### BACKGROUND OF THE DISCLOSURE

During the manufacture of electronic devices, fine patterns of features can be formed on a surface of a substrate by patterning the surface of the substrate and etching material from the substrate surface using, for example, gas-phase etching processes. As a density of devices on a substrate increases, it generally becomes increasingly desirable to form features with smaller dimensions.

Photoresist is often used to pattern a surface of a substrate prior to etching. A pattern can be formed in the photoresist by applying a layer of photoresist to a surface of the substrate, masking a surface of the photoresist, exposing an unmasked portion of the photoresist to radiation, such as ultraviolet light, and developing a portion of the photoresist to remove the unmasked or masked portion of the photoresist, while leaving the other of the unmasked and masked portion of the photoresist on the substrate surface.

The photoresist is typically spin-coated onto the surface of the substrate using a liquid solution. While such techniques work relatively well for several applications, spin-on coating techniques may not provide desired (relatively low) thickness or thickness uniformity of the photoresist on the substrate surface. Accordingly, improved methods of forming patternable material on the surface of the substrate are desired.

Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

Various embodiments of the present disclosure relate to methods of forming radiation-sensitive, patternable material on a surface of a substrate and to systems for forming the material. While the ways in which various embodiments of the present disclosure address drawbacks of prior methods are discussed in more detail below, in general, various embodiments of the disclosure provide methods of forming relatively thin, uniform radiation-sensitive, patternable material using gas-phase techniques.

In accordance with exemplary embodiments of the disclosure, a gas-phase method of forming radiation-sensitive, patternable material is provided. A gas-phase method of forming radiation-sensitive, patternable material can include providing a substrate within a reaction chamber of a gas-phase reactor; providing a precursor within the reaction chamber; and using the precursor, forming a polymeric material on a surface of the substrate, wherein the polymeric material forms the radiation-sensitive, patternable material. In accordance with examples of the disclosure, the precursor comprises one or more of an organic compound and an organosilicon compound. For example, the precursor can be or include one or more of: a siloxane, an organohalosilane, a carbosiloxane, a carbosilane, a silycarbodiimide, a silazane, and organic compounds comprising an acetate functional group and a cyclical group. In accordance with further examples, the precursor comprises a metal. In accordance with yet further examples, the step of forming the polymeric material comprises a chemical vapor deposition process, such as a plasma-enhanced chemical vapor deposition process. The chemical vapor deposition process can be a pulsed chemical vapor deposition process, in which one or more of a precursor, reactant, and plasma power are pulsed within the reaction chamber. In some cases, the chemical vapor deposition process may not be pulsed. A plasma can be formed using, for example, direct, indirect, and/or remote plasma apparatus. In some cases, the plasma can be formed using a capacitively-coupled direct plasma system. In some cases, the plasma can be formed using an inductively-coupled direct plasma system. In some cases, the plasma can be formed using (e.g., only) a noble gas. In other cases, the plasma may be formed using a reactant. In accordance with further examples of the disclosure, the method further includes a step of providing one or more reactants to the reaction chamber. Exemplary reactants include one or more metal reactants, hydrogen reactants, nitrogen reactants, carbon reactants, and oxygen reactants, in any combination.

In accordance with further embodiments, a method of forming patterned features on a surface of a substrate includes providing a substrate within a reaction chamber of a gas-phase reactor, providing a precursor within the reaction chamber, using the precursor to form a polymeric material on the surface of the substrate, exposing a portion of polymeric material to radiation to form exposed regions and unexposed regions within the polymeric material, and selectively removing one of the exposed regions or the unexposed regions to form the patterned features on the surface of the substrate. The radiation can include, for example, extreme ultraviolet radiation. In accordance with examples of these embodiments, the step of selectively removing can be or include a gas-phase process.

In accordance with further embodiments of the disclosure, a method of forming patterned features on a surface of a substrate includes providing a substrate within a reaction chamber of a gas-phase reactor; providing a precursor within the reaction chamber; using the precursor, forming a polymeric material on a surface of the substrate; exposing a portion of polymeric material to radiation to form exposed regions and unexposed regions within the polymeric material; and selectively forming material on one of the exposed regions or the unexposed regions.

In accordance with yet additional embodiments, a method of forming patterned features on a surface of a substrate includes forming a metal halide radiation-sensitive, patternable layer; exposing a portion of the metal halide radiation-sensitive, patternable layer to radiation to form exposed regions and unexposed regions; and selectively removing one of the exposed regions or the unexposed regions to form the patterned features. As above, the step of selectively removing can include a gas-phase process.

Exemplary methods can additionally include one or more of forming a capping layer, curing the patterned features, etching a portion of the substrate, and/or selectively forming or depositing material on the patterned features or the surface of the substrate. Further, one or more steps may be performed within the reaction chamber and/or within a reactor system.

In accordance with yet further exemplary embodiments of the disclosure, a reactor system is provided. An exemplary reactor system includes a gas-phase reactor for forming radiation-sensitive, patternable material (e.g., according to a method described herein); and a radiation exposure chamber for exposing a portion of the radiation-sensitive, patternable material to radiation to thereby form exposed regions and unexposed regions within the radiation-sensitive, patternable material. Exemplary reactor systems can further include a controller configured to effect one or more methods or method steps described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a method of forming a polymeric material on a surface of the substrate in accordance with exemplary embodiments of the disclosure.

FIG. 3 illustrates another method of forming a polymeric material on a surface of the substrate in accordance with exemplary embodiments of the disclosure.

FIG. 4 illustrates yet another method of forming a polymeric material on a surface of the substrate in accordance with exemplary embodiments of the disclosure.

FIG. 5 illustrates a method of forming a capping layer in accordance with exemplary embodiments of the disclosure.

FIG. 6 illustrates another method in accordance with exemplary embodiments of the disclosure.

FIG. 7 illustrates yet another method in accordance with exemplary embodiments of the disclosure.

FIGS. 8-17 illustrate structures in accordance with exemplary embodiments of the disclosure.

FIG. 18 illustrates a structure including a capping layer in accordance with additional exemplary embodiments of the disclosure.

FIG. 19 illustrates a reactor system in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood that the invention extends beyond the specifically disclosed embodiments and/or uses thereof and obvious modifications and equivalents thereof. Thus, it is intended that the scope of the invention disclosed should not be limited by the particular disclosed embodiments described below.

The present disclosure generally relates to gas-phase methods of forming radiation-sensitive, patternable material on a surface of a substrate. The gas-phase methods can be used to form relatively thin, uniform layers of radiation-sensitive, patternable material-especially, compared to layers of radiation-sensitive, patternable material deposited using spin-on techniques. Exemplary methods described herein can be used to form structures during the formation of, for example, electronic devices.

As used herein, the term substrate may refer to any underlying material or materials including and/or upon which one or more layers can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can additionally or alternatively include various features, such as recesses, lines, and the like formed within or on at least a portion of a layer of the substrate. In some cases, a substrate can include one or more of an underlayer, an absorber layer, and a hard mask layer at or near the surface of the substrate prior to forming the radiation-sensitive, patternable material on a surface of a substrate.

In some embodiments, film refers to a layer extending in a direction perpendicular to a thickness direction. In some embodiments, layer refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

In this disclosure, gas may include material that is a gas at normal temperature and pressure, a vaporized solid and/or a vaporized liquid, and may be constituted by a single gas or a mixture of gases, depending on the context. In some cases, such as in the context of deposition of material, the term precursor can refer to a compound that participates in the chemical reaction that produces another compound, and particularly to a compound that constitutes a film matrix or a main skeleton of a film. In some cases, the terms precursor and reactant can be used interchangeably. The term inert gas refers to a gas that does not take part in a chemical reaction to an appreciable extent and/or an otherwise relatively non-reactive gas from which excited species can be formed (e.g., using a plasma) to excite or interact with a precursor, but unlike a reactant, it may not become a part of a film matrix to an appreciable extent.

The term chemical vapor deposition can refer to a gas-phase process in which a precursor and often a reactant are provided to and/or are within a reaction chamber for an overlapping period of time. In some cases, a precursor alone can react, for example with a substrate surface or in a gas phase, to form a material on the substrate surface. In some cases, a precursor can react with activated species formed using a noble gas. In some cases, the precursor and a reactant (e.g., excited species derived from either) can react to form the material on the substrate surface. Plasma-enhanced chemical vapor deposition includes providing a plasma (e.g., by providing suitable plasma power) to form activated species from the precursor, a noble gas, and/or a reactant. Plasma-enhanced chemical vapor deposition processes can be performed using a direct, indirect and/or remote plasma. A pulsed plasma-enhanced chemical vapor deposition includes pulsing one or more of a precursor flow to a reaction chamber, a reactant flow to the reaction chamber, and a plasma power used to form a plasma during a deposition method.

The term cyclic deposition process or cyclical deposition process may refer to the sequential introduction of precursors (and/or reactants) into a reaction chamber to deposit a layer over a substrate and includes processing techniques, such as atomic layer deposition (ALD), molecular layer deposition (MLD), cyclical chemical vapor deposition (cyclical CVD), and hybrid cyclical deposition processes that include an ALD component and a cyclical CVD component. A cyclical deposition process can include plasma-enhanced processes, such as pulsed plasma-enhanced chemical vapor deposition processes.

The term atomic layer deposition may refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, and the like.

The term molecular layer deposition may refer to a vapor deposition process in which deposition cycles, typically a plurality of consecutive deposition cycles, are conducted in a process chamber to form layers comprising organic molecules.

In this disclosure, continuously can refer to one or more of without breaking a vacuum, without interruption as a timeline, without any material intervening step, without changing one or more conditions, immediately thereafter, as a next step, or without an intervening discrete physical or chemical structure or layer between two structures or layers in some embodiments. For example, a reactant and/or an inert or noble gas can be supplied continuously during two or more steps and/or cycles of a method.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, etc. in some embodiments. Further, in this disclosure, the terms including, constituted by and having can refer independently to typically or broadly comprising, comprising, consisting essentially of, or consisting of in some embodiments. In accordance with aspects of the disclosure, any defined meanings of terms do not necessarily exclude ordinary and customary meanings of the terms.

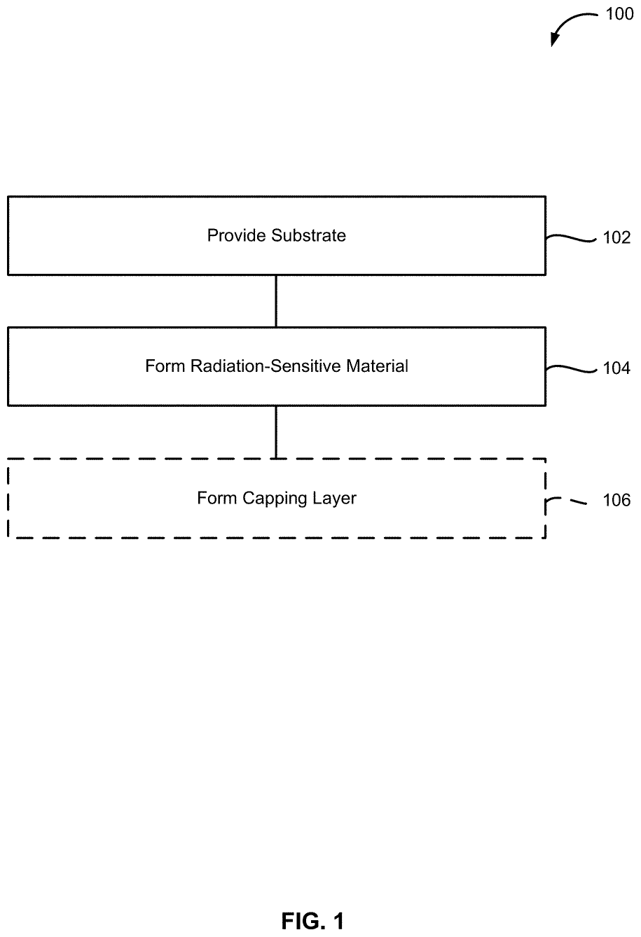

Turning now to the figures, FIG. 1 illustrates gas-phase method 100 of forming or depositing radiation-sensitive, patternable material on a surface of a substrate in accordance with exemplary embodiments of the disclosure. Method 100 includes the steps of providing a substrate within a gas-phase reaction chamber (step 102), forming (e.g., depositing) the radiation-sensitive, patternable material (step 104), and optionally forming a capping layer (step 106). Method 100 can also include an additional step, such as the additional steps noted below.

Step 102 includes providing a substrate, such as a substrate described herein. The substrate can include one or more layers, including one or more material layers, to be etched. The substrate can include several layers underlying and/or overlying the material layer(s) to be etched. Byway of examples, the substrate can include one or more of an underlayer, an absorber layer, and a hard mask layer—e.g., on a surface of the substrate.

During step 102, the reaction chamber can be brought to a desired temperature and pressure for subsequent processing (e.g., step 104). A particular temperature and pressure can depend on a variety of factors, including the material to be deposited. In accordance with examples of the disclosure, the reaction chamber or a susceptor therein can be controlled to a temperature of about 20° C. to about 400° C., about 50° C. to about 200° C., about 20° C. to about 250° C., or about 50° C. to about 150° C. A pressure within the reaction chamber can be from at least 700 Pa to at most 2000 Pa, or from at least 1000 Pa to at most 1800 Pa, or from at least 1300 Pa to at most 1500 Pa to, for example, facilitate formation of (at least initially) flowable polymeric material.

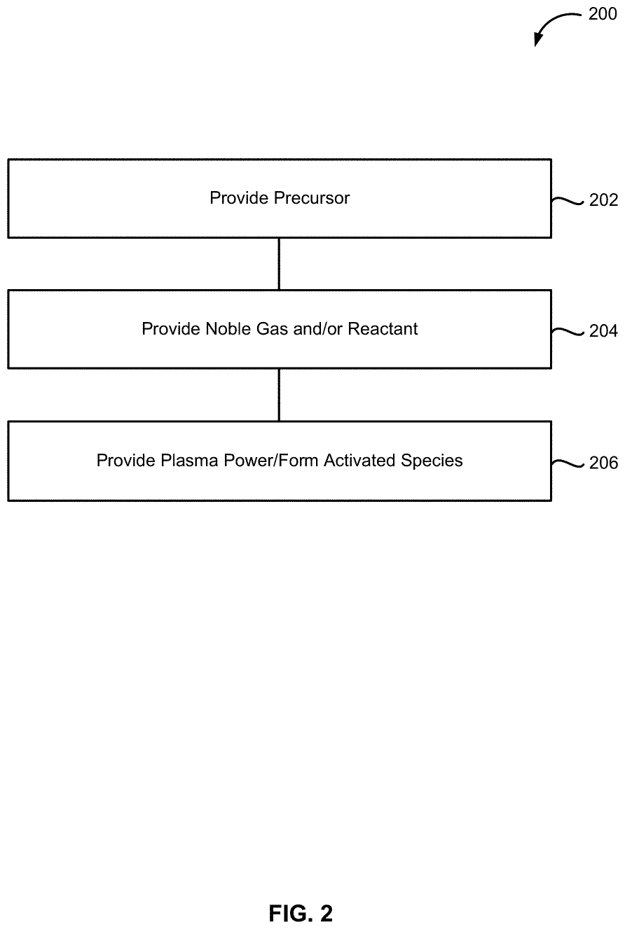

During step 104, the radiation-sensitive, patternable material is formed on the surface of the substrate. The radiation-sensitive, patternable material can be formed in a variety of ways, such as by forming or depositing a polymeric material that can be crosslinked (e.g., using radiation or excited species). Exemplary methods of forming the radiation-sensitive, patternable material are described below in connection with FIGS. 2-4.

With reference to FIG. 2, an exemplary method 200 of forming radiation-sensitive, patternable material is provided. The method generally includes providing a precursor within the reaction chamber (step 202), and using the precursor, forming a polymeric material on a surface of the substrate, wherein the polymeric material forms the radiation-sensitive, patternable material. Method 200 can also include providing a noble gas and/or reactant to the reaction chamber (step 204). In accordance with various examples of the disclosure, method 200 can include forming activated or excited species—e.g., using a plasma (step 206).

In accordance with examples of these embodiments, method 200 comprises a plasma-enhanced chemical vapor deposition process. The plasma-enhanced chemical vapor deposition process can be pulsed—or not. As noted above, a pulsed PECVD process can include pulsing one or more of a precursor, plasma power, and/or reactant to or within the reaction chamber. Although separately illustrated, two or more of steps 202-206 can be continuous and/or can overlap. For example, the noble gas and/or reactant can be continuously provided to the reaction chamber, and the precursor and/or plasma power can be pulsed. A deposition cycle can include one or more of such pulses. Method 200 can include one or more deposition cycles. Chemical vapor deposition methods, including plasma-enhanced chemical vapor deposition methods, can generally include mixing a vapor stream of a precursor with a reactant so as to form a polymerized material, and then depositing the polymerized material onto the surface of the substrate. The mixing and depositing aspects of the process may be concurrent, in a substantially continuous process.

In the cases of plasma-enhanced deposition processes, the plasma can be formed using, for example, direct, indirect, and/or remote plasma apparatus. In some cases, the plasma can be formed using a capacitively-coupled direct plasma system. In some cases, the plasma can be formed using an inductively-coupled direct plasma system. In some cases, the plasma can be formed using (e.g., only) a noble gas. In other cases, the plasma may be formed using a reactant (e.g., the reactant alone or combined with a noble or other gas, which is not incorporated into the deposited material to an appreciable extent.

Suitable precursors provided during step 202 can be in vapor form within the reaction chamber and can polymerize and/or can otherwise change phase from gas to liquid or solid within the reaction chamber to form polymeric material on the substrate surface. In accordance with further examples, the polymeric material can be crosslinked (e.g., using EUV radiation or excited species), such that the polymeric material can be patterned. In accordance with examples of these embodiments, a precursor provided during step 202 can be or include one or more of an organic compound and an organosilicon compound. Exemplary precursors can be or include, for example, one or more of a siloxane, an organohalosilane, a carbosiloxane, a carbosilane, a silycarbodiimide, a silazane, and organic compounds comprising an acetate functional group and a cyclical group. Some such compounds can be known as pre-ceramic polymer precursor. Other exemplary precursors include borosilanes, borosiloxanes, and borosilazanes. In many cases, the precursor comprise monomers of the compounds noted herein. In other cases, the compounds may include short chains of the monomers noted herein, so long as the precursor are suitable for gas-phase methods as described herein. In some cases, two or more of the precursors noted herein are provided to the reaction chamber in an overlapping manner and/or within the same method.

The precursor can comprise an organohalosilane. Organohalosilane can refer to a compound comprising silicon bonded to one or more organic groups and to one or more halogens. Organohalosilanes include organofluorosilanes, organochlorosilanes, organoborosilanes, and organoiodosilanes. An organosilane can be linear or branched, and can have a general formula of SiₙR₂₊₂₋ₘXₘ, wherein n is an integer from at least 1 to at most 3, m is an integer from at least 1 to at most 2n+1, the R groups are organic groups, and the X groups are halogens. Each R and X group can be independently selected. Exemplary organic groups include hydrocarbyls, such as an alkyl, alkenyl, or aryl. Exemplary halogens include F, Cl, Br, and I. Exemplary organohalosilanes include alkylchlorosilanes, such as dimethyldichlorosilane and ethyltrichlorosilane. Organohalosilane precursors can be suitably employed for forming polyorganohalosilane-containing EUV-sensitive layers.

In some embodiments, the silicon precursor comprises a carbosiloxane. Carbosiloxane can refer to a linear, branched, or cyclic compound that includes silicon bonded to one or more organic groups and to one or more oxygen atoms. Particular examples of carbosiloxane include cyclocarbosiloxanes. Suitable cyclocarbosiloxanes can comprise alkyl substituents, such as methyl, ethyl, propyl, butyl, pentyl, and hexyl. An exemplary cyclocarbosiloxane includes:

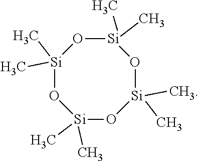 [SMILES: C[Si]1(C)O[Si](C)(C)O[Si](C)(C)O[Si](C)(C)O1]

In accordance with further examples, one or more of the methyl groups in the above formula can be independently replaced with another short-chain (e.g., C2-C4) hydrocarbon. Carbosiloxane precursors can be suitably employed for forming polycarbosiloxane-containing EUV-sensitive layers.

In some embodiments, the silicon precursor comprises an alkylamine-substituted cyclosiloxane. Suitable alkylamine-substituted syclosiloxanes include 2-diethylamino-2,4,6,8-tetramethylcyclotetrasiloxane. Alkylamine-substituted cyclosiloxanes can be suitably used for forming EUV-sensitivy layers that comprise polysiloxanes having alkylamine side-groups.

In some embodiments, the silicon precursor comprises a carbosilane. Carbosilane can refer to a compound comprising silicon bonded to one or more organic groups. Suitable carbosilanes can be linear, branched, or cyclic. In some embodiments, the silicon precursor comprises a carbosilane. Particular exemplary carbosilanes, i.e., linear carbosilanes, can be represented by the general formula:

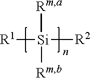

where n is an integer from at least 1 to at most 6, m is an index from at least 1 to at most n, R¹, R², the R^{m,a}, and the R^{m,b} are independently selected from H and alkyl. Suitable alkyls include methyl, ethyl, probyl, butyl, pentyl, and hexyl. Carbosilane precursors can be suitably used for forming EUV-sensitive layers that comprise polysilanes having carbon-containing side groups such as polysilanes having alkyl side groups.

In some embodiments, the silicon precursor comprises a silane comprising a carbodiimide group. An example of such a precursor includes silylcarbodiimide, i.e., SiH₃—N═C═N—H. Such precursors can be advantageously used for forming EUV-sensitive layers comprising polysilylcarbodiimides or polysilsesquicarbodiimides.

In some embodiments, the silicon precursor comprises a silazane. A silazane can refer to a compound that includes silicon and nitrogen. Suitably, a silazane can refer to any hydride of silicon and nitrogen having a straight, branched, or cyclic chain of silicon and nitrogen atoms joined by covalent bonds. A silazane can further refer to an organic derivative of such a compound. Silazanes can be suitably used for forming EUV-sensitive layers comprising polysilazanes.

Exemplary silazanes can be represented by the formula:

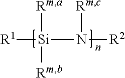

where n is an integer from at least 1 to at most 6, m is an index from at least 1 to at most n, R¹, R², the R^{m,a}, and the R^{m,b} are independently selected from H, alkyl, and silyl. Suitable silazanes include SiH₃—NH—SiH₃

Examples of silazanes can be represented by the following formulas

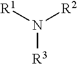

where R₁, R₂, and R₃ are independently selected from SiH₃, SiXH₂, SiX₂H, and SiX₃, wherein X is a halogen such as F, Cl, Br, or I.

Additional examples of silazanes can be represented by the following formula,

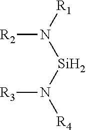

where R₁, R₂, R₃, and R₄ are independently selected from SiH₃, SiXH₂, SiX₂H, and SiX₃, wherein X is a halogen such as F, Cl, Br, or I.

Additional examples of silazanes can be represented by the following formula,

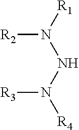

where R₁, R₂, R₃, and R₄ are independently selected from SiH₃, SiXH₂, SiX₂H, and SiX₃, wherein X is a halogen such as F, Cl, Br, or I.

Additional examples of silazanes can be represented by the following formula,

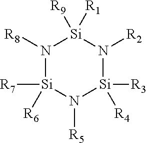

where R₁, R₂, R₃, R₄, R₅, R₆, R₇, R₈, and R₉ are independently selected from H, alkyl, haloalkyl, and silyl. In some embodiments, the silazane comprises

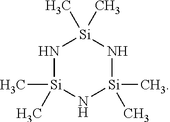

In some embodiments, the precursor can comprise an organic compound. Suitable organic compounds include aromatic diols such as bisphenol A. Such compounds can be suitably employed for forming EUV-sensitive layers comprising organic polymers.

A combined flowrate of the precursor and carrier gas to the reaction chamber can be from about 3.0 slm to about 100 slm. In some cases, the precursor is provided to the reaction chamber with the aid of a carrier gas, such as nitrogen, hydrogen, or a noble gas. If pulsed, a duration of a pulse can be from about 0.05 to at most 0.2 seconds, and inter-pule time can be from about 0.2 s to at most 2 s.

With reference again to FIG. 2, during step 204, one or more noble gas(es) and/or reactant(s) are provided to the reaction chamber. In some cases, activated species can be formed from the noble gas(es) and/or reactant(s). Exemplary reactants include one or more metal reactants, one or more hydrogen reactants, one or more nitrogen reactants, one or more carbon reactants, one or more halogen reactants, and one or more oxygen reactants.

As used herein, a metal reactant comprises one or more metals, such as W, Ge, Sb, Te, Nb, Ta, V, Ti, Zr, Hf, Rh, Fe, Cr, Mo, Au, Pt, Ag, Ni, Cu, Co, Zn, Al, In, Sn, and Bi. Exemplary metal reactants include, metal halides, metal alkyls, metal alkylamides, metal hydrides, and heteroleptic metal-containing compounds, for example heteroleptic metal-containing compounds comprising a metal center and at least two different ligands selected from a halide ligand, an alkyl ligand, an alkylamide ligand, and a hydride ligand.

As used herein, a hydrogen reactant comprises hydrogen. Exemplary hydrogen reactants include H₂, N₂H₂, NH₃, mixtures of H₂ and a noble gas, and mixtures of H₂ and N₂.

As used herein, a nitrogen reactant comprises nitrogen. Exemplary nitrogen reactants include N₂, NH₃, N₂H₂, N₂O, NO, NO₂, and mixtures of N₂ and a noble gas, and mixtures of H₂ and N₂.

As used herein, a carbon reactant comprises carbon and, typically, hydrogen.

Exemplary carbon reactants include alkyls such as CH₄ and aromatic substances such as benzene and toluene.

As used herein, an oxygen reactant comprises oxygen. Exemplary oxygen reactants include O₂, H₂O, N₂O, NO, NO₂, and O₃.

Exemplary noble gases include helium and argon.

By way of examples, a hydrogen reactant and one or more other reactant(s) or noble gas(es) can be provided to the reaction chamber. The inclusion of a hydrogen reactant (e.g., H₂ to about 100 volume percent of the reactant) is thought to facilitate flowability of the precursor as it polymerizes and can be used to tune a degree of polymerization of the precursor or derivative thereof.

A flowrate of the reactant and/or noble gas to the reaction chamber can be from about 0.1 to about 10 slm. If the reactant and/or noble gas is pulsed, a duration of a pulse can be from about 0.1 to about 10 seconds. As noted above, in some cases, the reactant and/or noble gas can be continuously provided to the reaction chamber during steps 202-206.

During step 206, plasma power can be provided to form excited species—e.g., from one or more of the reactant(s) and/or noble gas(es). The power may be used to form a direct plasma (within the reaction chamber), an indirect plasma, or a remote plasma. The power used to form the plasma can be from about 20 to about 150 W. A frequency of the power can be from about 10 to about 50 MHz. If pulsed, a duration of a pulse in step 206 can be from about 0.5 s to about 4.0 seconds.

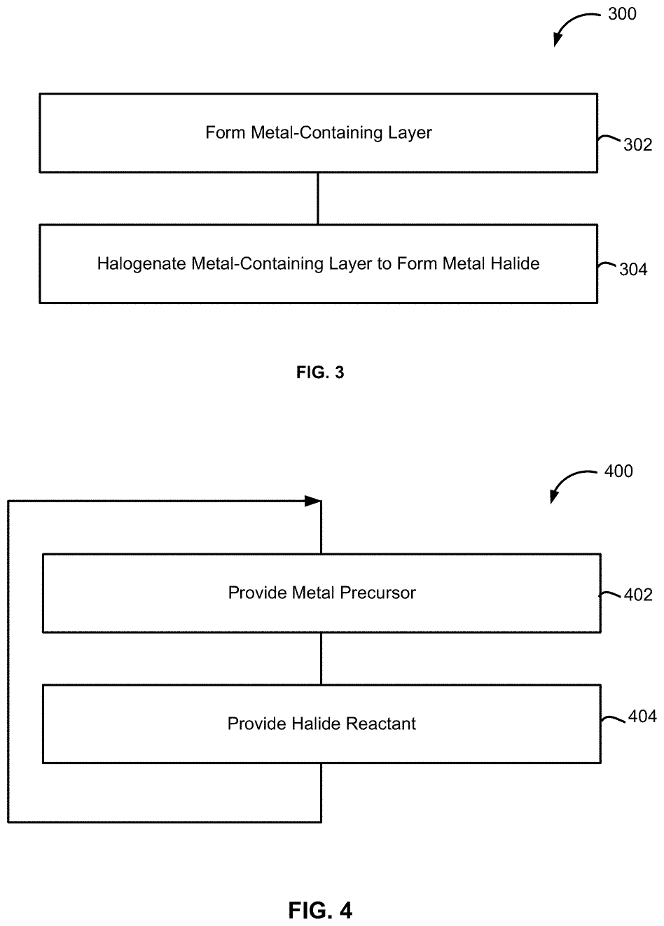

FIG. 3 illustrates an exemplary method 300 of forming a metal halide radiation-sensitive, patternable material suitable for step 104. Method 300 includes the steps of forming a metal-containing layer (step 302) and halogenating the metal-containing layer to form a metal halide (step 304).

In this case, the radiation-sensitive, patternable material is or includes a metal halide. In this context, a metal halide refers to material that includes a metal element and a halogen. Metal halides can include oxymetalhalides that additionally include oxygen. Exemplary metal elements include Nb, Ta, V, Ti, Zr, Hf, Rh, Fe, Cr, Mo, W, Co, Ge, Sb, Te, Au, Pt, Ag, Ni, Cu, Zn, Al, In, Sn, and/or Bi. Exemplary halogens include chlorine, bromine, and fluorine. Particular metal halides can be selected from one or more of the metal halides from the group consisting of NbCl₄, NbI₅, NbOCl₃, TaCl₅, TaI₅, TaF₅, TaBr₅, VF₄, VF₅, VBr₃, V₂O₂F₄, VOCl₂, VOCl₃, VOF₃TiF₄, ZrI₄, ZrCl₄, ZrBR₄, ZnCl₂, ZnI₂, HfCl₄, Hfl₄, RhBr₃, FeBr₃, FeBr₂, CrF₅, Mo₆Cl₂, MoCl₄, MoI₃, MoBr₃, WOBr₄, WoCl₄, ZrF₆(H₂O)₂, Col, CoCl₂(H₂O)₂, GeF₂, GeF₄, SbF₃, SbF₅, Te₂Br, AuF₃, AuBr, PtBr₄, AgF₃, NiBr₂, CuBr₂, AlCl₃, AlI₃, InBr₃, SnCl₂, SnBr₂, and BiF₅.

During step 302, a metal-containing layer can be deposited using any suitable method, such as CVD, a cyclical deposition process, a physical vapor deposition process, or the like. For example, a metal oxide, a metal nitride, or the like can be formed during step 302. By way of particular examples, a TiO₂ or TiN layer can be formed during step 302.

During step 304, the metal-containing layer formed during step 302 is halogenated. Step 304 can include any suitable halogenation treatment, such as any thermal, liquid, plasma, and/or radical-based technique. Byway of specific examples, NF₃ can be used to halogenate TiOx to form radiation-sensitive, patternable material comprising TiF₄, e.g. using a remote plasma in which the plasma gas comprises NF₃. Use of other exemplary halogenating reactants, such as F₂, Cl₂, Br₂, I₂, HF, HCl, HBr, and HI, are also contemplated.

FIG. 4 illustrates another method 400 of forming the radiation-sensitive, patternable material, wherein the material comprises a metal halide. In this case, the metal halide can be formed directly. As illustrated, method 400 includes a step of providing a metal precursor (step 402) and providing a halide reactant (step 404). In a CVD process, the metal precursor and the halide reactant can be provided at least partially overlapping in time within the reaction chamber. In a cyclic process, such as an ALD process, the metal precursor and the halide reactant can be provided in separate pulses, which can optionally be separated by a purge step.

The precursor provided during step 402 can include any of the metals noted above in connection with step 302. The halide reactant can include any halogen-containing reactant, such as Cl₂, Br₂, F₂, I₂, NF₃, HF, HCl, HBr, HI, a haloalkane, or the like. In the case of cyclical processes, steps 402 and 404 can be repeated until a desired film thickness is reached.

Returning to FIG. 1, as noted above, method 100 can include step 106 of forming a capping layer. The capping layer can protect radiation-sensitive, patternable material formed during step 104 against surrounding/degrading ambient conditions priorto exposure to radiation at wavelengths used in lithography—especially at EUV wavelengths. Use of a capping layer may be particularly useful in connection with metal halide radiation-sensitive, patternable material. However, unless otherwise noted, the disclosure is not limited to such application.

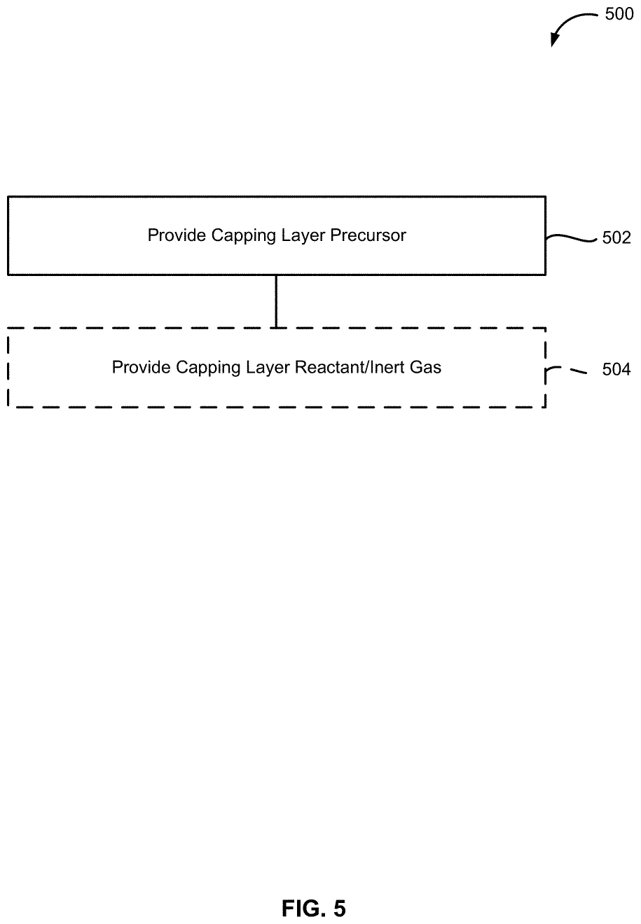

FIG. 5 illustrates an exemplary method 500 of forming a capping layer that is suitable for use as step 106. In some cases, step 106 is performed in-situ within the same reaction chamber used during step 104.

As illustrated, method 500 includes providing a capping layer precursor (step 502) and optionally providing a capping layer reactant and/or inert gas (step 504). In accordance with examples of these embodiments, step 106 does not include using precursors/reactants in a plasma process containing H, O, N, because these elements could cause dehalogenation of an underlying (e.g., metal halide) polymer.

The precursor provided during step 502 can include silicon. Silicon is known to have a low absorption cross-section for EUV light, and therefore the EUV light will mostly pass through the thin Si layer and react with the underlying radiation-sensitive, patternable material during an exposure step.

Byway of examples, step 502 can include providing a capping layer precursor selected from one or more of SiCl₄ or Si₂Cl₆. Argon can be used as the inert gas in step 504. Other processes (e.g., plasma, thermal, radical) capable of depositing or otherwise forming an in-situ capping layer without the presence of reactive gases (H, O, N) are also suitable.

The capping layer formed during method 500 can be relatively thin. For example, a thickness of the capping layer can be greater than 0 nm and less than 10 nm or greater than 0 nm and less than 5 nm.

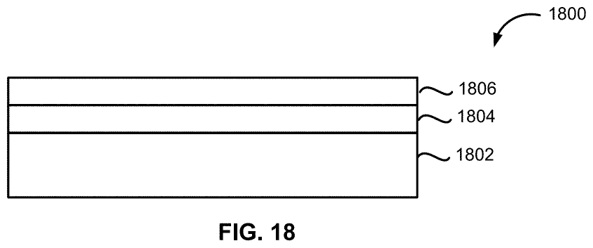

FIG. 18 illustrates a structure 1800, including a substrate 1802, a radiation-sensitive, patternable material layer 1804, and a capping layer 1806. Radiation-sensitive, patternable material layer 1804 can be formed in accordance with step 104 of method 100 and capping layer 1806 can be formed in accordance with step 106 of method 100. A thickness of the radiation-sensitive, patternable material layer/polymeric material 1804 can be greater than zero or greater than 0.3 nm and less than 10 nm or less than 5 nm.

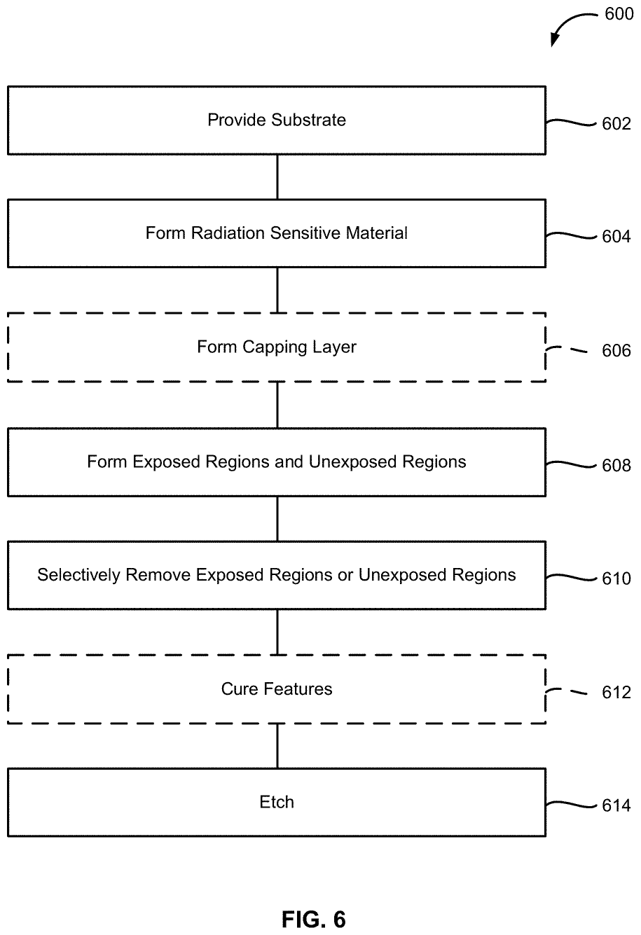

FIG. 6 illustrates another method 600 in accordance with examples of the disclosure. Method 600 includes the steps of providing a substrate within a gas-phase reaction chamber (step 602), forming (e.g., depositing) the radiation-sensitive, patternable material (step 604), optionally forming a capping layer (step 606), forming exposed and unexposed regions (step 608), selectively removing exposed or unexposed regions (step 610), optionally curing features (step 612), and etching (step 614).

Method 600 is similar to method 100, except method 100 includes the additional steps 608-614. Steps 602-606 of method 600 can be the same or similar to steps 102-106 described above.

During step 608, portions of the polymeric material/radiation-sensitive, patternable material are exposed to radiation to form exposed regions and unexposed regions within the polymeric material formed during step 604. The exposed regions can be formed by masking the radiation-sensitive, patternable material and exposing the unmasked regions to radiation, such as EUV radiation. In some cases, step 608 can be performed using the same reactor systems as steps 602-606. In some cases, the step of exposing a portion of the metal halide radiation-sensitive, patternable layer to radiation comprises providing an oxidizing environment. In these cases, step 608 can result in EUV-induced (e.g., metal) oxide formation in exposed areas, in addition to polymerization.

During step 610, one of the exposed regions or the unexposed regions are selectively removed from the surface of the substrate to form patterned features on the surface of the substrate.

Generally, step 610 can include a gas-phase process (either by plasma or thermal treatment) and/or include a liquid phase. In accordance with examples of the disclosure, step 610 is performed in a gas-phase reactor—e.g., the same reaction chamber or reactor system used during one or more of steps 602-606.

In some cases, particularly in the case of metal halide polymeric material, step 610 can be performed by heating the substrate to allow the material in the unexposed or exposed regions to evaporate. By way of examples, the substrate can be heated to a temperature of about 50° C. to about 500° C. or about 100° C. to about 300° C.

Once patterned features are formed by selectively removing the unexposed or exposed regions, the features can be cured during step 612. A temperature during the step of curing can be greater than 200° C. or between about 100° C. and about 500° C. or between about 200° C. and about 400° C. Curing can be done thermally using a soak anneal or a rapid thermal anneal. Additionally or alternatively, curing can comprise exposing the substrate to one or more of a plasma, to radicals, to infrared radiation, to ultraviolet radiation, to extreme ultraviolet radiation, and microwaves.

During step 614, a portion of the substrate is etched using the patterned features as an etch mask.

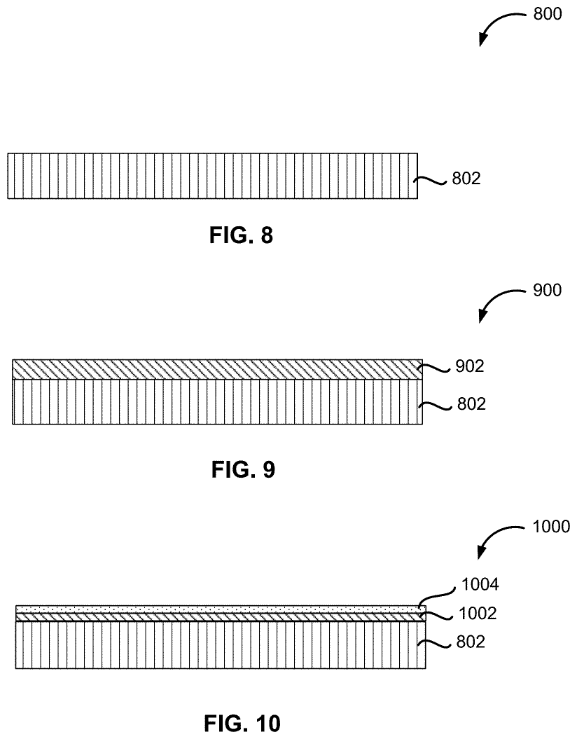

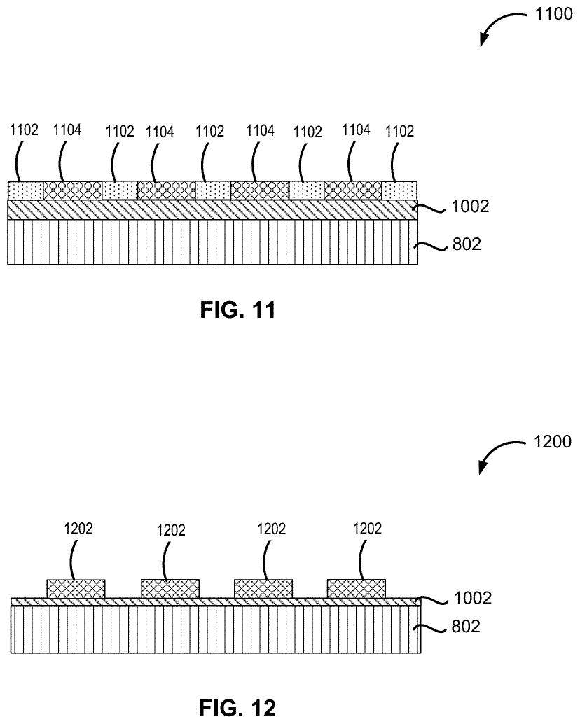

FIG. 8-12 illustrate structures 800-1200 during formation steps 602-610. In the illustrated example, method 300 was used in step 604.

Structure 800 includes a substrate 802. Substrate 802 can be or include any substrate as described herein.

Structure 900 includes substrate 802 and a metal-containing layer, such as a metal containing layer formed during step 302.

Structure 1000 include a halogenated (metal halide) layer 1004 and can include a remaining metal-containing layer 1002. Halogenated layer 1004 can be formed as described above in connection with step 304.

Structure 1100 includes unexposed regions 1102 and exposed regions 1104 formed within halogenated layer 1004. Unexposed regions 1102 and exposed regions 1104 can be formed using step 608, described above.

Unexposed regions 1102 or exposed regions 1102 can be selectively removed to form structure 1200, including patterned features 1202. The exposed or unexposed regions can be removed as described above in connection with step 610 and optionally cured as described in connection with step 612. Patterned features 1202 can then be used as an etch mask. In some cases, material can be selectively deposited on the patterned features or the surface of the substrate.

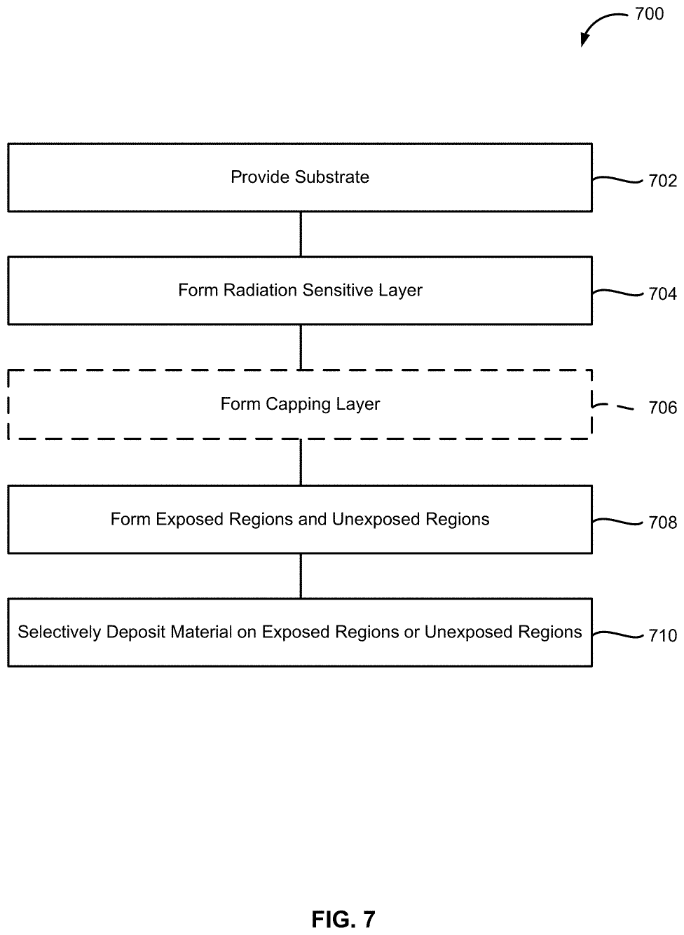

FIG. 7 illustrates another method 700 in accordance with additional embodiments of the disclosure. Method 700 includes the steps of providing a substrate within a gas-phase reaction chamber (step 702), forming (e.g., depositing) the radiation-sensitive, patternable material (step 704), optionally forming a capping layer (step 706), forming exposed and unexposed regions (step 708), and selectively depositing material on one of the exposed regions or the unexposed regions (step 710). Method 700 is similar to method 600, except method 700 includes a step 710 of selectively depositing material on one of the exposed regions or the unexposed regions, rather than steps 610 and 614. Steps 702-708 can be the same as steps 602-608 described above. Further, although not separately illustrated, method 700 can include a step of curing patterned features, as described above, after step 708 and prior to step 710.

During step 710, after exposed and unexposed regions are formed, material is selectively deposited on one of the exposed regions or the unexposed regions. The selective deposition can be performed using a one-step or cyclical process. By way of example, a cyclical deposition process, such as PEALD or pulsed PECVD, can be used to selectively deposit material. Alternatively, a continuous process such as CVD or PECVD can be used to selectively deposit material.

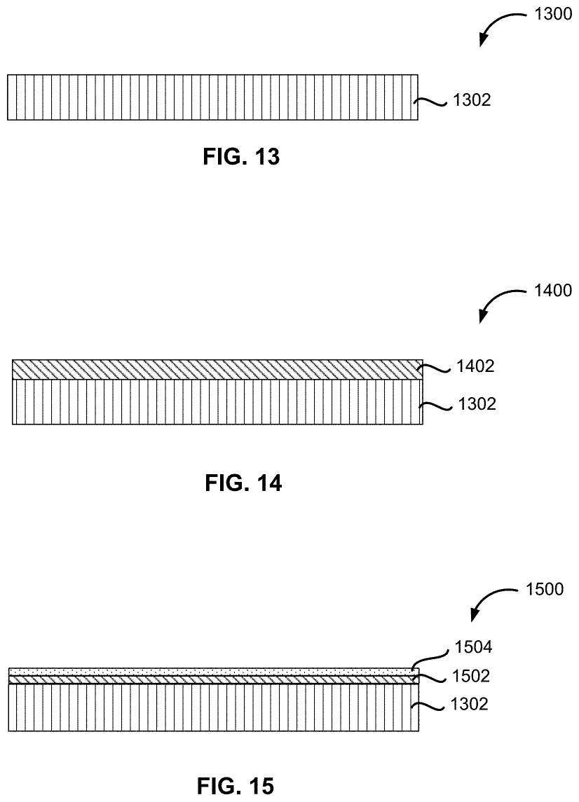

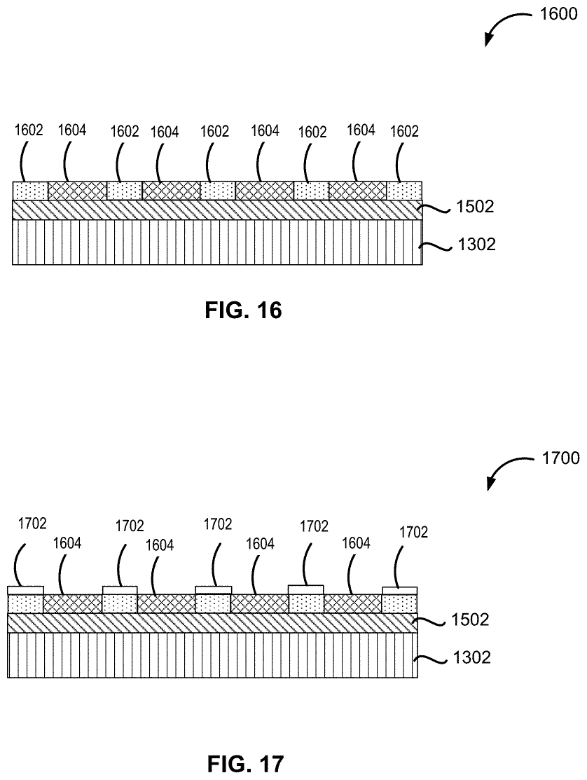

FIGS. 13-17 illustrate structures 1300-1700 during a selective deposition process.

Structure 1300 includes a substrate 1302, which can be or include any substrate as described herein.

Structure 1400 includes substrate 1302 and a metal-containing layer 1402, such as a metal containing layer formed during step 302.

Structure 1500 includes a halogenated (metal halide) layer 1504 and can include a remaining metal-containing layer 1502. Halogenated layer 1504 can be formed as described above in connection with step 304.

Structure 1600 includes unexposed regions 1602 and exposed regions 1604 formed within halogenated layer 1004.

Material 1702 can be selectively deposited on unexposed regions 1602 or exposed regions 1604. In the illustrated example, material 1702 is selectively deposed on unexposed regions 1602, relative to exposed regions 1604. In other cases, material can be selectively deposited onto exposed regions 1604, relative to unexposed regions 1602.

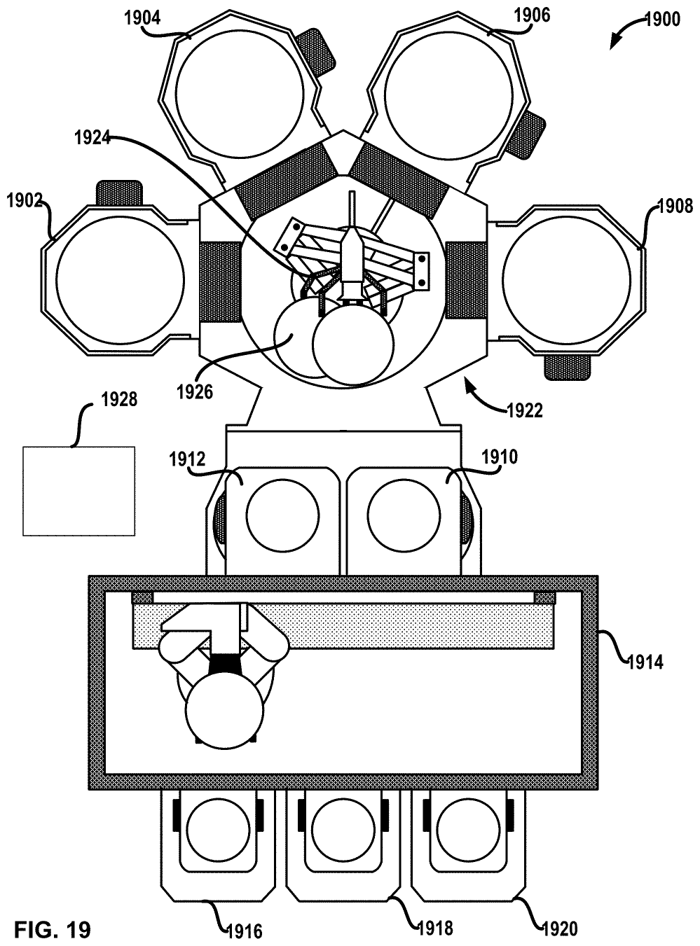

FIG. 19 illustrates an exemplary reactor system 1900 in accordance with examples of the disclosure. Reactor system 1900 can be used for a variety of applications, such as to perform methods described herein and/or to form a structure including radiation-sensitive, patternable material as described herein. As noted above, one or more steps of method 100 can be performed within a single system (e.g., system 1900) and/or within a single reactor or reaction chamber of system 1900.

In the illustrated example, reactor system 1900 includes four separate reactors 1902-1908, each reactor including a single reaction chamber. In the illustrated embodiment, a first substrate handler 1914 is used to move substrates (e.g., semiconductor wafers) 1926 from one or more cassettes 1916-1920 to an intermediate loading station 1910, 1912. Cassettes 1916-1920 (e.g., Front Opening Unified Pods (FOUP)) may each hold multiple substrates and engage with loading stations for loading cassettes into the system 1900. Subsequently, a second substrate handler 1924 is used to move the substrates 1926 from intermediate loading station 1910, 1912 to a reaction chamber of a reactor 1902-1908. In the system of FIG. 19, four substrates can be processed at a time. However, it will be appreciated that the system may be configured to process more substrates or fewer substrates (e.g., a single substrate). System 1900 may further include a gas injection and purge system (not shown) fluidly coupled to the reaction chambers, as well as a heating system (not shown) to elevate temperatures within a reaction chamber and/or the processing stations to a desired processing temperature. Further, system 1900 may include a controller 1928 configured to control the operation of the system—e.g., to perform a method as described herein.

In accordance with examples of the disclosure, at least one of reactors 1902-1908 is configured to perform steps 102, 104 (604, 704), and optionally step 106 (606, 706) as described herein. In accordance with further examples of the disclosure, at least one of reactors 1902-1908 comprises a radiation exposure chamber for exposing a portion of the radiation-sensitive, patternable material to radiation to thereby form exposed regions and unexposed regions within the radiation-sensitive, patternable material—e.g., as descried above in connection with steps 608, 708. In accordance with yet further examples, at least one of reactors 1902-1908 comprises a removal chamber for selectively removing one of the exposed regions and unexposed regions within the radiation-sensitive, patternable material—e.g., as described above in connection with step 610. In accordance with yet additional examples, at least one of reactors 1902-1908 is configured to selectively deposit material as described above in connection with step 710.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

We claim:

1. A gas-phase method of forming radiation-sensitive, patternable material, the method comprising the steps of:
providing a substrate within a reaction chamber of a gas-phase reactor;
providing a precursor within the reaction chamber; and
using the precursor, forming a polymeric material on a surface of the substrate,
wherein the polymeric material forms a radiation-sensitive, patternable material.

2. The method of claim 1, wherein the step of forming the polymeric material comprises forming a plasma.

3. The method of claim 2, wherein the plasma is formed within the reaction chamber.

4. The method of claim 1, wherein the precursor comprises one or more of an organic compound and an organosilicon compound.

5. The method of claim 1, wherein the precursor comprises one or more of: a siloxane, an organohalosilane, a carbosiloxane, a carbosilane, a silylcarbodiimide, a silazane, and organic compounds comprising an acetate functional group and a cyclical group.

6. The method of claim 1, wherein the method comprises a pulsed plasma-enhanced chemical vapor deposition process.

7. The method of claim 1, further comprising a step of providing one or more reactants to the reaction chamber.

8. The method of claim 7, wherein the step of providing one or more reactants and the step of providing the precursor overlap.

9. The method of claim 7, wherein the one or more reactants comprise a metal reactant.

10. The method of claim 7, wherein the one or more reactants comprise a hydrogen reactant.

11. The method of claim 7, wherein the one or more reactants comprise a nitrogen reactant.

12. The method of claim 7 wherein the one or more reactants comprise a carbon reactant.

13. The method of claim 7, wherein the one or more reactants comprise an oxygen reactant.

14. The method of claim 7, wherein the step of forming the polymeric material comprises forming a plasma, and
wherein the step of providing one or more reactants and the step of forming the plasma overlap.

15. The method of claim 1, wherein a thickness of the polymeric material is greater than zero and less than 10 nm.

16. The method of claim 2, wherein the step of forming the plasma comprises forming active species from a noble gas.

17. The method of claim 1, wherein the substrate comprises one or more of an underlayer, an absorber layer, and a hard mask layer.

18. A method of forming patterned features on a surface of a substrate, the method comprising the steps of:
providing a substrate within a reaction chamber of a gas-phase reactor;
providing a precursor within the reaction chamber;
using the precursor, forming a polymeric material on the surface of the substrate;
exposing a portion of polymeric material to radiation to form exposed regions and unexposed regions within the polymeric material; and
selectively removing one of the exposed regions or the unexposed regions to form the patterned features on the surface of the substrate.

19. The method of claim 18, wherein the radiation comprises extreme ultraviolet radiation.

20. The method of claim 18, wherein the step of selectively removing comprises a gas-phase process.

21. The method of claim 18, further comprising a step of curing the patterned features.

22. The method of claim 18, further comprising a step of etching a portion of the substrate using the patterned features as an etch mask.

23. The method of claim 18, further comprising a step of selectively depositing material on the patterned features or the surface of the substrate.

24. A method of forming patterned features on a surface of a substrate, the method comprising the steps of:
providing a substrate within a reaction chamber of a gas-phase reactor;
providing a precursor within the reaction chamber;
using the precursor, forming a polymeric material on a surface of the substrate;
exposing a portion of polymeric material to radiation to form exposed regions and unexposed regions within the polymeric material; and
selectively depositing material on one of the exposed regions or the unexposed regions.

25. A method of forming patterned features on a surface of a substrate, the method comprising the steps of:
forming a metal halide radiation-sensitive, patternable layer;
exposing a portion of the metal halide radiation-sensitive, patternable layer to radiation to form exposed regions and unexposed regions; and
selectively removing one of the exposed regions or the unexposed regions to form the patterned features.

26. The method of claim 25, wherein the step of forming the metal halide radiation-sensitive, patternable layer comprises forming a metal-containing layer and subsequently halogenating the metal-containing layer.

27. The method of claim 25, wherein the step of selectively removing comprises a gas-phase process.

28. The method of claim 25, wherein the step of exposing the portion of the metal halide radiation-sensitive, patternable layer to radiation comprises providing an oxidizing environment.

29. The method of any of claim 1, further comprising a step of forming a capping layer.

30. The method of claim 29, wherein a thickness of the capping layer is greater than 0 and less than 10 nm or less than 5 nm.

31. The method of claim 29, wherein the capping layer comprises silicon.

32. The method of claim 1, wherein the steps are performed within a reactor system.

33. A reactor system comprising:
a gas-phase reactor for forming radiation-sensitive, patternable material according to the method of claim 1; and
a radiation exposure chamber for exposing a portion of the radiation-sensitive, patternable material to radiation to thereby form exposed regions and unexposed regions within the radiation-sensitive, patternable material.

34. The reactor system of claim 33, further comprising a removal chamber for selectively removing one of the exposed regions and the unexposed regions within the radiation-sensitive, patternable material.
